(19) United States
(12) Patent Application Publication
(10) Pub. No.: US 2023/0238223 A1
(43) Pub. Date: Jul. 27, 2023

(54) CARRIER RINGS WITH RADIALLY-VARIED PLASMA IMPEDANCE

(71) Applicant: Lam Research Corporation, Fremont, CA (US)

(72) Inventors: Nick Ray Linebarger, JR., Beaverton, OR (US); Fayaz A. Shaikh, Lake Oswego, OR (US); Kang Il Lee, Osan-si (KR)

(21) Appl. No.: 18/002,614

(22) PCT Filed: Jun. 21, 2021
(86) PCT No.: PCT/US2021/038210

§ 371 Date: Dec. 20, 2022

Related U.S. Application Data
(60) Provisional application No. 62/705,412, filed on Jun. 25, 2020.

(51) Int. Cl. H01J 37/32; H01L 21/687; C23C 16/458; C23C 16/505

(52) U.S. Cl. CPC H01J 37/32715; H01L 21/68721; C23C 16/4585; C23C 16/505; H01J 2237/2007; H01J 37/32733; H01J 37/32899; H01J 37/32082; H01J 2237/332

(57) ABSTRACT

Carrier rings with radially-varied plasma impedance are provided herein. In some embodiments, a carrier ring may include an outer ring that holds a removable inner ring. The outer ring may be formed of a dielectric material such as ceramic. The inner ring may be formed of a metal such as aluminum to provide a desired impedance. In some other embodiments, a carrier ring is formed from a single piece with radially-varying impedances.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

The present disclosure relates to carrier rings that support a semiconductor wafer during processing within a processing chamber.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

In one aspect, a carrier ring is provided that includes multi-station plasma processing system is provided, wherein the system includes: a first processing station comprising a first set of support features configured to support a substrate at a first set of positions on a backside of the substrate when the substrate is processed at the first processing station; and a second processing station comprising a second set of support features configured to hold the substrate at a second set of positions on the backside of the substrate when the substrate is processed at the second processing station, wherein the first set of positions are non-overlapping with the second set of positions.

In one aspect, a carrier ring is provided that includes an outer ring formed from a dielectric material and having an engagement feature and an inner ring formed from a metal, where the inner ring engages with the engagement feature of the outer ring and where the inner ring is configured to support a semiconductor wafer during processing within a processing chamber.

In another aspect, a plasma processing system is provided that includes a shower-pedestal and a substrate support, where the substrate support includes an inner portion with a first plasma impedance, the inner portion being configured to hold a substrate at a spaced apart relationship from the shower-pedestal, and an outer portion with a second plasma impedance, the second plasma impedance being different than the first plasma impedance.

### BRIEF DESCRIPTION OF THE DRAWINGS

FIGS. 1A and 1B are schematic diagrams of substrate processing systems in accordance with certain disclosed embodiments.

FIG. 2 is a top view of a multi-station processing tool in accordance with certain disclosed embodiments.

FIG. 3 is a schematic view of a multi-station processing tool in accordance with certain disclosed embodiments.

FIGS. 4A and 4B are perspective views of a wafer carrier ring in accordance with certain disclosed embodiments.

FIG. 5A is a cross-sectional view of a wafer carrier ring in accordance with certain disclosed embodiments.

FIG. 5B is a cross-sectional view of a wafer carrier ring showing radially-varying electrical impedances in accordance with certain disclosed embodiments.

FIG. 6 is a schematic diagram of an example control module for controlling substrate processing systems in accordance with certain disclosed embodiments.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it s not intended to limit the disclosed embodiments.

Portions of the present disclosure relate to plasma-enhanced chemical vapor deposition (PECVD), which is a type of plasma deposition that is used to deposit thin films from a gas state (i.e., vapor) to a solid state on a substrate such as a wafer. PECVD systems convert a liquid precursor into a vapor precursor, which is delivered to a chamber. PECVD systems may include a vaporizer that vaporizes the liquid precursor in a controlled manner to generate the vapor precursor. Typically, chambers used for PECVD use ceramic pedestals for supporting the wafer during processing, which enables processing under high temperatures.

Most PECVD deposition and other processing to form the devices occur on the front face of a wafer, e.g., top-side. As the deposited layers build up, they can introduce stress in the wafer. This stress can cause the wafer to bow, which is undesirable. Where bowing is significant, it can deleteriously affect subsequent processing steps. Sometimes, depositing materials on the back-side of the wafer may counteract wafer bowing and stress. However, to deposit on a back-side of the wafer, the wafer has to be flipped and loaded as back-side up. Flipping the wafer introduces additional problems, such as additional handling, potential exposure to particles, and/or reduction in processing yield.

Embodiments of the disclosure provide implementations of a carrier ring with radially-varying plasma impedance. The carrier ring may be formed from radially-varying materials and/or a radially-varying structure, such that the carrier ring has a radially-varying plasma impedance. The radially-varying plasma impedance may provide plasma tuning in backside substrate deposition. Changes in the impedance presented by a carrier ring can result in changes to plasma intensity during backside deposition, with increases in impedance generally resulting in decreases in plasma intensity and with decreases in impedance generally resulting in increases in plasma intensity. In one implementation, a carrier ring is formed from an inner metal ring and an outer ceramic ring such that the ring as a whole presents a desired impedance. The impedance may be varied by varying the material(s) selected for the inner ring (e.g., which ceramic is selected or even switching to non-ceramic materials) and the material(s) selected for the outer ring (e.g., which metal is selected or even switching to non-metallic materials). In another implementation, a carrier ring is formed of a single material with properties that vary radially. As a particular example, a carrier ring may be formed from a material having an impedance that varies depending on its thickness. In such an example, a carrier ring may have a greater or lesser thickness in an outer circumference and a lesser or greater thickness in an inner circumference, such that the ring has the desired impedances at various radial distances. In yet another implementation, a carrier ring is formed from two or more materials that vary radially either smoothly or in one or more steps (e.g., an inner region of a first material that is permanently or semi-permanently joined to an outer region of a second material, with transitions between the materials that are either gradual or distinct)

Controlling (e.g., varying) the impedance in these manners may facilitate various backside and/or frontside reaction processes such as deposition processes, etching processes, plasma-enhanced chemical vapor deposition (PECVD), chemical vapor deposition (CVD), atomic layer deposition (ALD), plasma enhanced atomic layer deposition (PEALD), low pressure chemical vapor deposition (LPCVD), etc. As a specific example, the carrier rings may be designed to provide a desired impedance to plasma during PECVD backside and/or frontside deposition processes. As an example, an inner portion of the carrier rings may be relatively thin and/or formed of metal to decrease the impedance to ground and thus increase plasma intensity in the vicinity of the inner portion of the carrier rings and an outer portion of the carrier rings may be relatively thick and/or formed of ceramic to increase the impedance to ground and thus decrease plasma intensity in the vicinity of the outer portions of the carrier ring. By varying the thickness of the carrier rings in a radial direction, varying the material of the carrier rings in a radial direction, varying the relative sizes of the metal and ceramic rings, and/or by altering the materials of the inner and outer rings, the impedance of the carrier ring can be tuned along a radial direction to achieve a desired impedance gradient and plasma intensity gradient. Thus the plasma intensity along the edge of the substrate can be finely tuned.

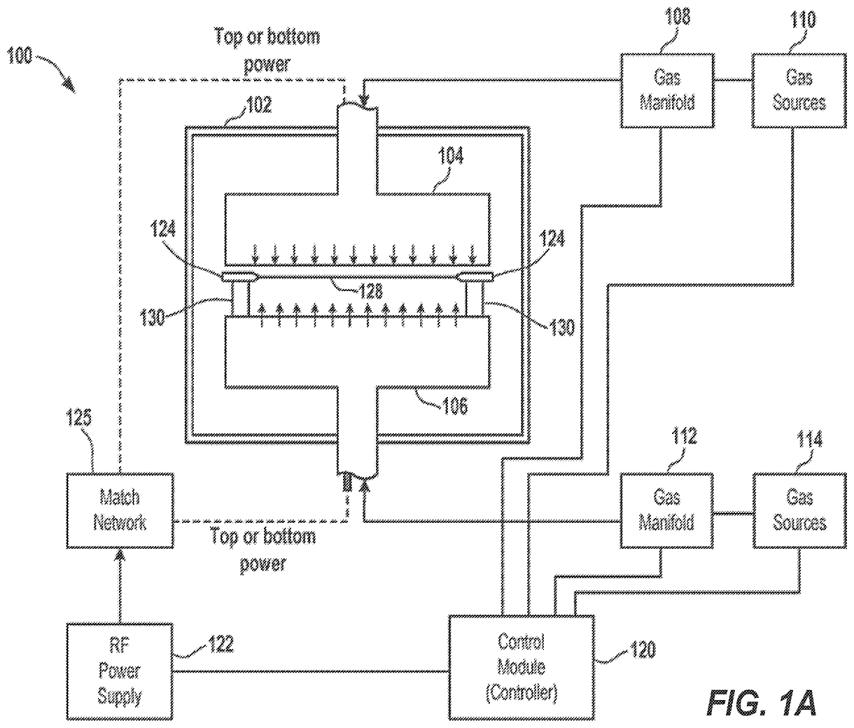

Multi-level semiconductor processing flows used to manufacture advanced memory and logic chips have caused substrates to warp significantly in compressive and tensile directions. Due to this moderate to severe substrate warpages, processing conditions of various manufacturing processes are compromised causing process control issues, lithography chucking and overlay issues, which sometimes cause increases in yield loss. In one embodiment, one way to control the warpage is to deposit a sacrificial film or multiple films on the opposite side (i.e., back-side) of the substrate to compensate the warpage in opposite direction resulting in flattening of the substrate. The traditional dual electrode radio-frequency (“RF”) PECVD systems have one gas-flowing electrode that can be RF or ground. Typically, the gas flowing electrode (also referred to as a showerhead 104 in FIG. 1) is on the top side of the PECVD reactor causing the reactants to flow on the front-side of the wafer causing deposition only on the front-side of the wafer.

In accordance with one embodiment, an RF PECVD system is disclosed that has dual gas-flowing electrodes. Either one of the electrodes can be an RF electrode to provide AC fields enabling plasma enhancements for chemical vapor deposition (CVD) film depositions. This dual gas-flowing electrode PECVD system is capable of selectively depositing films on both or only one side of the wafer. In one example, a gas-flowing pedestal (referred to herein as a “shower-pedestal” or “show-ped”) can hold the wafer for transfers within the chamber between adjacent stations or outside the chamber via standard transfer mechanisms based on the equipment setup, yet be able to flow gases from the back-side of the wafer.

In one embodiment, the back-side gas flow enables the PECVD deposition on the back-side of the wafer while the front-side gas flow can deposit on the front side of the wafer. The system can be set up to selectively enable the side of the deposition by turning on and off the reactants that cause the film deposition and replacing them with non-reacting gases (e.g., inert gases). Another aspect of this system is to be able to control the distance of side of the substrate from the reactant flowing gases. This control enables achieving the deposition profile and film properties that are needed for the applications such as back-side compensation.

In another embodiment, the show-ped and showerhead include configurations that provide showerhead-like features that enable proper reactant mixing and providing appropriate flow dynamics for PECVD deposition processes on the back-side of the wafer, or front side. Additionally, some embodiments enable for a controllable gap that can suppress or allow the plasma on the desired (one or both) sides of the wafer for deposition. The gaps being controlled can include, e.g., a gap spacing between a top side of the wafer and the top surface of the showerhead 104 as shown in FIGS. 1A and 1B, and a gap spacing between a back side of the wafer and the top surface of the show-ped 106 as shown in FIGS. 1A and 1B. For example, while the back side of the wafer is being deposited, the gap between the top side of the wafer and the top surface of the showerhead is minimized.

The show-ped 106 is further configure to include a showerhead hole pattern and inner plenums for even distribution of gases. A showerhead hole pattern and inner plenums that provide even distribution of gases allows for process gases to be delivered toward the bottom of the wafer c with a suitably even distribution. The embodiments also allow for the gas-flowing pedestal (i.e., show-ped) to have an active heater to get the process gas to the proper temperature. The combination of the show-ped 106 and showerhead 104 allows for the concurrent function of both of key attributes. The show-ped 106 can, in one embodiment, still heat the wafer and provide the wafer transfer features within the reactor chamber or outside the reactor, while the showerhead 104 components allows for process gas flow. The gas-flowing pedestal (i.e., show-ped) disclosed herein therefore enable implementation of traditional PECVD processes to deposit on either side of the wafer, selectively. These configurations are also configured to selectively RF power the top or bottom electrode, and dynamically enable/disable the plasma on the side of the wafer that needs deposition.

Broadly speaking, the show-ped provides several advantages for combating the stress and bowing issues by depositing a film on the back side of the wafer. The back side film counteracts the stress from the front side deposition to result in a neutral stress (or substantially neutral stress, e.g., less than about +/−150 MPa) wafer that shows no bowing (or substantially no bowing, e.g., less than about 150 μm of bow). If the film deposited on the front side is tensile, then the back side film should also be tensile to balance out the overall stress. Likewise, if the front side film is compressive, then the back side film should also be compressive. The back side film may be deposited through various reaction mechanisms (e.g., chemical vapor deposition (CVD), plasma enhanced chemical vapor deposition (PECVD), atomic layer deposition (ALD), plasma enhanced atomic layer deposition (PEALD), low pressure chemical vapor deposition (LPCVD), etc.). In various cases, plasma enhanced chemical vapor deposition is used due to the high deposition rate achieved in this type of reaction.

Certain deposition parameters can be tuned to produce a back side film having a desired stress level. One of these deposition parameters is the thickness of the deposited back side film. Thicker films induce more stress in the wafer, while thinner films of the same composition and deposited under the same conditions induce less stress in the wafer. Therefore, in order to minimize the amount of material consumed in forming the back side layer, this layer may be deposited relatively thinly under conditions that promote formation of a highly stressed film.

In addition or as an alternative to tuning deposition parameters, the impedance properties of a wafer carrier ring can be tuned to produce a film having desired properties such as stress levels and radial uniformity or non-uniformity. In particular, embodiments disclosed herein include a carrier ring having radially-varied impedances to plasma. Such a carrier ring can improve the uniformity of films on a first side of a wafer such as by reducing thickness variations between edge portions and central portions of such films, without resulting in additional or excess deposition on the opposite side of the wafer. While much of the present disclosure refers to deposition of films on a backside of a substrate, the wafer carrier rings and other elements disclosed herein can also be used in the deposition of films on a frontside of a substrate, can also be used in the etching of films on a frontside or a backside of a substrate, and can also be used in other semiconductor processing operations on a frontside or a backside of a substrate.

As mentioned, stacks of deposited materials are especially likely to result in wafer stress and bowing. One example stack that may cause these problems is a stack having alternating layers of oxide and nitride (e.g., silicon oxide/silicon nitride/silicon oxide/silicon nitride, etc.). Another example stack likely to result in bowing includes alternating layers of oxide and polysilicon (e.g., silicon oxide/polysilicon/silicon oxide/polysilicon, etc.). Other examples of stack materials that may be problematic include, but are not limited to, tungsten and titanium nitride. The materials in the stacks may be deposited through chemical vapor deposition techniques such as plasma enhanced chemical vapor deposition (PECVD), low pressure chemical vapor deposition (LPCVD), metal organic chemical vapor deposition (MOCVD), atomic layer deposition (ALD), plasma enhanced atomic layer deposition (PEALD), or through direct metal deposition (DMD), etc. These examples are not intended to be limiting. Certain disclosed embodiments may be useful whenever wafer stress and/or bowing are induced due to material present on the front side of the wafer.

The front side stacks may be deposited to any number of layers and thicknesses. In a typical example, the stack includes between about 32-72 layers, and has a total thickness between about 2-4 μm. The stress induced in the wafer by the stack may be between about −500 MPa to about +500 MPa, resulting in a bow that is frequently between about 200-400 82 m (for a 300 mm wafer), and even greater in some cases.

The material deposited on the back side of the wafer may be a dielectric material in various embodiments. In some cases, an oxide and/or nitride (e.g., silicon oxide/silicon nitride) is used. Examples of silicon-containing reactants that may be used include, but are not limited to, silanes, halosilanes, and aminosilanes. A silane contains hydrogen and/or carbon groups, but does not contain a halogen. Examples of silanes are silane (SiH₄), disilane (Si₂H₆), and organo silanes such as methylsilane, ethylsilane, isopropylsilane, t-butylsilane, dimethylsilane, diethylsilane, di-t-butylsilane, allylsilane, sec-butylsilane, thexylsilane, isoamylsilane, t-butyldisilane, di-t-butyldisilane, and the like. A halosilane contains at least one halogen group and may or may not contain hydrogens and/or carbon groups. Examples of halosilanes are iodosilanes, bromosilanes, chlorosilanes and fluorosilanes. Although halosilanes, particularly fluorosilanes, may form reactive halide species that can etch silicon materials, in certain embodiments described herein, the silicon-containing reactant is not present when a plasma is struck. Specific chlorosilanes are tetrachlorosilane (SiCl₄), trichlorosilane (HSiCl₃), dichlorosilane (H₂SiCl₂), monochlorosilane (ClSiH₃), chloroallylsilane, chloromethylsilane, dichloromethylsilane, chlorodimethylsilane, chloroethylsilane, t-butylchlorosilane, di-t-butylchlorosilane, chloroisopropylsilane, chloro-sec-butylsilane, t-butyldimethylchlorosilane, thexyldimethylchlorosilane, and the like. An aminosilane includes at least one nitrogen atom bonded to a silicon atom, but may also contain hydrogens, oxygens, halogens and carbons. Examples of aminosilanes are mono-, di-, tri- and tetra-aminosilane (H₃Si(NH₂)₄, H₂Si(NH₂)₂, HSi(NH₂)₃ and Si(NH₂)₄, respectively), as well as substituted mono-, di-, tri- and tetra-aminosilanes, for example, t-butylaminosilane, methylaminosilane, tert-butylsilanamine, bis(tertiarybutylamino)silane (SiH₂(NHC(CH₃)₃)₂ (BTBAS), tert-butyl silylcarbamate, SiH(CH₃)—(N(CH₃)₂)₂, SiHCl—(N(CH₃)₂)₂, (Si(CH₃)₂NH)₃ and the like. A further example of an aminosilane is trisilylamine (N(SiH₃)). Other potential silicon-containing reactants include tetraethyl orthosilicate (TEOS), and cyclic and non-cyclic TEOS variants such as tetramethoxysilane (TMOS), fluorotriethoxysilane (FTES), Trimethylsilane (TMS), octamethyltetracyclosiloxane (OMCTS), tetramethylcyclotetrasiloxane (TMCTSO), dimethyldimethoxysilane (DMDS), hexamethyldisilazane (HMDS), hexamethyldisiloxane (HMDSO), hexamethylcyclotrisiloxane (HMCTSO), dimethyldiethoxysilane (DMDEOS), methyltrimethoxysilane (MTMOS), tetramethyldisiloxane (TMDSO), divinyltetramethyldisiloxane (VSI₂), methyltriethoxysilane (MTEOS), dimethyltetramethoxydisiloxane (DMTMODSO), ethyltriethoxysilane (ETEOS), ethyltrimethoxysilane (ETMOS), hexamethoxydisilane (HMODS), bis(triehtoxysilyl)ethane (BTEOSE), bis(trimethoxysilyl)ethane (BTMOSE), dimethylethoxysilane (DMEOS), tetraethoxydimethyldisiloxane (TEODMDSO), tetrakis(trimehtylsiloxy)silane (TTMSOS), tetramethyldiethoxydisiloxane (TMDEODSO), triethoxysilane (TIEOS), trimethoxysilane (TIMEOS), or tetrapropoxysilane (TPOS).

Example nitrogen-containing reactants include, but are not limited to, ammonia, hydrazine, amines (e.g., amines bearing carbon) such as methylamine, dimethylamine, ethylatnine, isopropylamine, t-butylamine, di-t-butylamine, cyclopropylamine, sec-butylamine, cyclobutylamine, isoamylamine, 2-methylbutan-2-amine, trimethylamine, diisopropylamine, diethylisopropylamine, di-t-butylhydrazine, as well as aromatic containing amines such as anilines, pyridines, and benzylamines. Amines may be primary, secondary, tertiary or quaternary (for example, tetraalkylammonium compounds). A nitrogen-containing reactant can contain heteroatoms other than nitrogen, for example, hydroxylamine, t-butyloxycarbonyl amine and N-t-butyl hydroxylamine are nitrogen-containing reactants.

Examples of oxygen-containing co-reactants include oxygen, ozone, nitrous oxide, carbon monoxide, nitric oxide, nitrogen dioxide, sulfur oxide, sulfur dioxide, oxygen-containing hydrocarbons (CxHyOz), water, mixtures thereof, etc.

The flow rate of these reactants will depend greatly on the type of reaction through which the back side layer is deposited. Where CVD/PECVD are used to deposit the back side layer, the flow rate of the silicon-containing reactant may be between about 0.5-10 mL-min (before atomization), for example between about 0.5-5 ml/min. The flow rate of a nitrogen-containing reactant, oxygen-containing reactant, or other co-reactant may be between about 3-25 standard liters per minute (SLM), for example between about 3-10 SLM.

In certain implementations the back side layer may be removed after further processing. Where this is the case, the composition of the back side layer should be chosen such that it can be easily removed from the substrate at an appropriate time. In this regard, there should be a high selectivity between the material of the back side layer (e.g., the dielectric) and the material of the underlying substrate (e.g., silicon) in the desired removal chemistry.

The thickness of the back side layer may depend on the amount of stress induced by the deposition on the front side of the wafer, as well as the conditions under which the back side layer is deposited. The back side layer may be deposited to a thickness at which the stress in the wafer becomes negligible (e.g., less than about 150 MPa). In these or other embodiments, the back side layer may be deposited to a thickness at which the wafer bow becomes negligible (e.g., less than about 150 μm of bow). In some cases, this corresponds to a back side layer thickness between about 0.1-2 μm, for example between about 0.3-2 μm, or between about 0.1-1 μm, or between about 0.3-1 μm. Where silicon nitride is used to form the back side layer, a film having a thickness of about 0.3 μm is sufficient to mitigate a bow of about 50-200 μm. As mentioned above, a higher stress back side layer may be used to reduce the required thickness of the layer. This helps conserve materials and reduce costs.

It should be appreciated that the present embodiments can be implemented in numerous ways, such as a process, an apparatus, a system, a device, or a method. Several embodiments are described below.

Deposition of films is in one embodiment implemented in a plasma enhanced chemical vapor deposition (PECVD) system. The PECVD system may take many different forms. The PECVD system includes one or more chambers or “reactors” that house one or more wafers and are suitable for wafer processing. Each chamber or reactor may include multiple processing stations. Each chamber or reactor may house one or more wafers for processing. The one or more chambers maintain the wafer in a defined position or positions (with or without motion within that position, e.g. rotation, vibration, or other agitation). A wafer undergoing deposition may be transferred from one station to another within a reactor chamber during the process. Of course, the film deposition may occur entirely at a single station or any fraction of the film may be deposited at any number of stations.

While in process, each wafer is held in place by a pedestal, wafer chuck and/or other wafer holding apparatus. For certain operations, the apparatus may include a heater such as a heating plate to heat the wafer.

FIG. 1A illustrates a substrate processing system 100, which is used to process a wafer 128. The system includes a chamber 102. A center column is configured to support a pedestal for when a top surface of the substrate 128 is being processed, e.g., a film is being formed on the top surface. The pedestal, in accordance with embodiments disclosed herein, is referred to as a show-ped 106. A showerhead 104 is disposed over the show-ped 106. In one embodiment, the showerhead 104 is electrically coupled to power supply 122 via a match network 125. The power supply 122 is controlled by a control module 120, e.g., a controller. In other embodiments, it is possible to provide power to the show-ped 106 instead of the showerhead 104. The control module 120 is configured to operate the substrate processing system 100 by executing process input and control for specific recipes. Depending on whether the top surface of the substrate 128 is receiving a deposited film or the bottom surface of the substrate 128 is receiving a deposited film, the controller module 120 sets various operational inputs, for a process recipe, e.g., such as power levels, timing parameters, process gasses, mechanical movement of the wafer 128, height of the wafer 128 off of the show-ped 106, etc.

The center column can also include lift pins, which are controlled by a lift pin control. The lift pins are used to raise the wafer 128 from the show-ped 106 to allow an end-effector to pick the wafer and to lower the wafer 128 after being placed by the end end-effector. The end effector (not shown), can also place the wafer 128 over spacers 130. As will be described below, the spacers 130 are sized to provide a controlled separation of the wafer 128 between a bottom surface of the showerhead 104 that is facing the wafer and a top surface of the show-ped 106 that is facing the wafer.

The substrate processing system 100 further includes a gas manifold 108 that is connected to gas sources 110, e.g., gas chemistry supplies from a facility and/or inert gases. Depending on the processing being performed over a top surface of the substrate, the control module 120 controls the delivery of gas sources 110 via the gas manifold 108. The chosen gases are then flown into the showerhead 104 and distributed in a space volume defined between a face of the showerhead 104 that faces that wafer 128 when the wafer is resting over the pedestal 140.

The substrate processing system 100 further includes a gas manifold 112 that is connected to gas sources 114. e.g., gas chemistry supplies from a facility and/or inert gases. Depending on the processing being performed over a bottom surface of the substrate, the control module 120 controls the delivery of gas sources 114 via the gas manifold 112. The chosen gases are then flown into the showerhead 104 and distributed in a space volume defined between a face of the show-ped 106 that faces an under surface/side of the wafer 128 when the wafer is resting over on the spacers 130. The spacers 130 provide for a separation that optimizes deposition to the under surface of the wafer 128, while reducing deposition over the top surface of the wafer. In one embodiment, while deposition is targeted for the under surface of the wafer 128, an inert gas is flown over the top surface of the wafer 128 via the showerhead 104, which pushes reactant gas away from the top surface and enables reactant gases provided from the show-ped 106 to be directed to the under surface of the wafer 128.

Further, the gases may be premixed or not. Appropriate valving and mass flow control mechanisms may be employed to ensure that the correct gases are delivered during the deposition and plasma treatment phases of the process. Process gases exit chamber via an outlet. A vacuum pump (e.g., a one or two stage mechanical dry pump and/or a turbomolecular pump) draws process gases out and maintains a suitably low pressure within the reactor by a close loop controlled flow restriction device, such as a throttle valve or a pendulum valve.

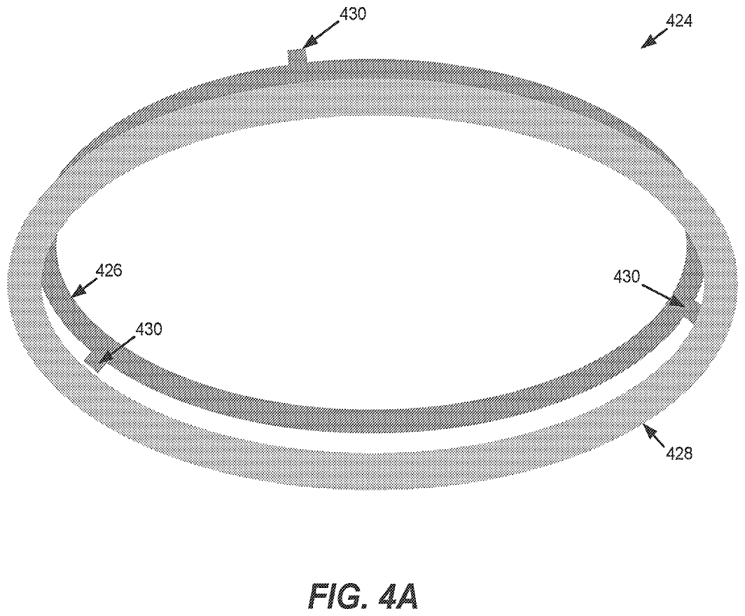

Also shown is a carrier ring 12.4 that encircles an outer region of the show-ped 106. Carrier ring 124 may have radially-varied impedances, as discussed in more detail in connection with FIGS. 4A, 4B, 5, and 6. When the top surface of the wafer 128 is being processed, e.g., a material is being deposited thereon, the carrier ring 124 is configured to sit over a carrier ring support region that is a step down from a wafer support region in the center of the pedestal show-ped 106. The carrier ring 124 includes an outer edge side of its disk structure, e.g., outer radius, and a wafer edge side of its disk structure, e.g., inner radius, that is closest to where the wafer 128 sits. The wafer edge side of the carrier ring 124 includes a plurality of contact support structures which are configured to lift the wafer 128 when the carrier ring 124 is held by the spacers 130.

In FIG. 1B, spider forks 132 are used to lift and maintain the carrier ring 124 in its process height, to enable deposition on the under surface of the wafer 128). The carrier ring 124 is therefore lifted along with the wafer 128 and can be rotated to another station, e.g., in a multi-station system.

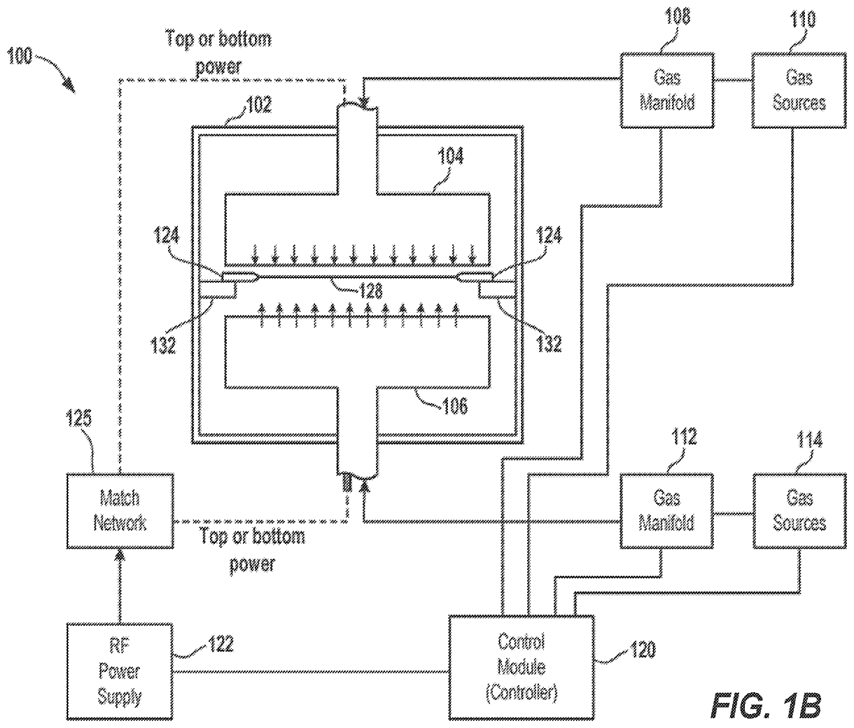

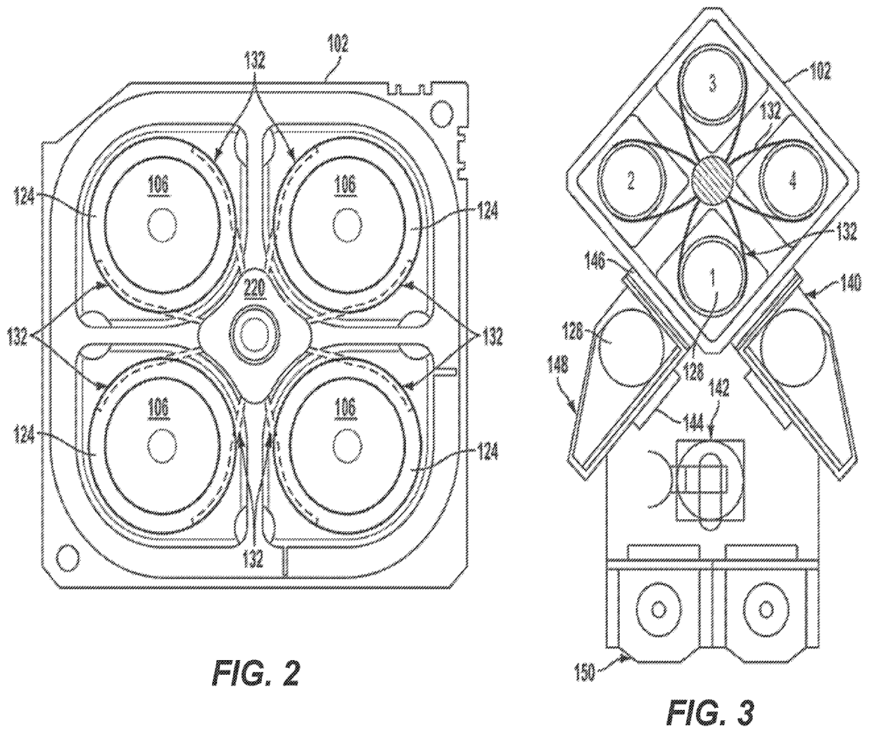

FIG. 2 illustrates a top view of a multi-station processing tool, wherein four processing stations are provided. The embodiment of FIGS. 1A and 1B illustrate a chamber 102, which can be implemented in chamber 102 of FIGS. 2 and 3, which have four chamber stations. FIGS. 2 and 3 provide top views of a chamber portion with a top chamber portion removed for illustration, wherein four stations are accessed by spider forks 132. Each spider fork 132, or fork includes a first and second arm, each of which is positioned around a portion of each side of the show-ped 106, In this view, the spider forks 132 are drawn in dash-lines, to convey that they are below the carrier ring 124. The spider forks 132, using an engagement and rotation mechanism 220 are configured to raise up and lift the carrier rings 124 from a lower surface of the carrier rings 124 from the stations simultaneously, and then rotate at least one or more stations before lowering the carrier rings 124 where at least one of the carrier rings supports a wafer 128 to a next location so that further plasma processing, treatment and/or film deposition can take place on respective wafers 12.8. As noted above, in one embodiment, the spider forks 132 can be used to raise the wafer 128 to a height that enables deposition on a backside of the wafer 128, while substantially preventing deposition on a topside of the wafer 128, e.g., as shown in FIG. 1B.

FIG. 3 shows a schematic view of an embodiment of a multi-station processing tool with an inbound load lock 148 and an outbound load lock 140. A robot 142, at atmospheric pressure, is configured to move substrates 128 from a cassette loaded through a pod 150 into inbound load lock 148 via an atmospheric port 144. Inbound load lock 148 is coupled to a vacuum source (not shown) so that, when atmospheric port 144 is closed, inbound load lock 148 may be pumped down. Inbound load lock 148 also includes a chamber transport port 146 interfaced with processing chamber 102. Thus, when chamber transport 146 is opened, another robot (not shown) may move the substrate from inbound load lock 148 to a show-ped 106 of a first process station for processing.

The depicted processing chamber 102 comprises four process stations, numbered from 1 to 4 in the embodiment shown in FIG. 3. In some embodiments, processing chamber 102 may be configured to maintain a low pressure environment so that substrates may be transferred using a carrier ring 124 among the process stations without experiencing a vacuum break and/or air exposure. Each process station depicted in FIG. 3 a show-ped 106 that is configured to deliver a process gas when backside deposition is to occur. During backside deposition, whether spacers or spider forks are used to raise the wafer off of the show-ped 106, the showerhead 104 is configured to supply an inert gas over the top surface of the substrate to prevent or reduce deposition over the top surface of the wafer 106.

FIG. 3 also depicts spider forks 132 for transferring wafers within processing chamber 102 and lifting the wafer 128 during backside deposition. As will be described in more detail below, the spider forks 132 can also rotate and enable transfer of wafers from one station to another. The transfer occurs by enabling the spider forks 132 to lift carrier rings 124 from an outer undersurface, which then lifts the wafer, and then rotates the wafer and carrier 124 together to the next station. In one configuration, the spider forks 132 are made from a ceramic material to withstand high levels of heat during processing.

In other embodiments, instead of using spider forks 132 to lift and transfer the wafers, a paddle type structure can also function to lift and transfer the wafers. Paddles can be disposed between the stations, similar to the way the spider forms 132 sit, and can function in the same way. Thus, for easy of understanding, references to spider forms 132 should be understood to also apply to paddle configurations, which can provide the control lifting (e.g., during backside wafer deposition) and transfers between stations.

Broadly speaking, the embodiments disclosed herein are for a system to deposit PECVD films on a front and/or back side of the wafer with dynamic control. One embodiment includes a dual gas-flowing electrode for defining a capacitively-coupled PECVD system. The system will include a gas-flowing showerhead 104 and a show-ped 106. In one embodiment, the gas-flowing pedestal (i.e., show-ped) is a combination showerhead and pedestal, which enables deposition on a back-side of the wafer. The electrode geometry combines features of a showerhead, e.g., such as a gas mixing plenum, holes, hole-pattern, gas jet preventing baffle, and features of a pedestal, e.g., such as embedded controlled heater, wafer-lift mechanisms, ability to hold plasma suppression rings, and movability. This enables the transfer of wafers and the processing of gasses with or without RF power from the pedestal.

In one embodiment, the system has a wafer lift mechanism that allows tight control of parallelism of the substrates against the electrodes. In one embodiment, this is achieved by setting up the lift mechanism parallel to the two electrodes and controlling manufacturing tolerances, e.g., spindle or lift pins mechanisms. Another embodiment is defined by raising the wafer lift parts, but this option does not allow dynamic control of the side that gets deposited.

In one configuration, the lift mechanism allows controlling of the distance dynamically during the deposition process to control the side of the deposition, profile of the deposition, and deposition film properties. The system further allows selective enabling/disabling of the side where reactants are flown. One side can flow the reactant and the other side can flow inert gases to suppress the deposition and plasma.

In one embodiment, the gap between the side of the wafer that does not need plasma or film deposition may be tightly controlled to suppress plasma and thus reduce or eliminate plasma damage. in one example, this system allows minimal gap from about 2 mm to about 0.5 mm, and in another embodiment from about 1 mm to about 0.05 as limited by the wafer bow, and such gap can be controlled. In one embodiment, this gap depends upon the process conditions.

In one embodiment, the gas-flowing pedestal (i.e., show-ped) enables, without limitation: (a) thermal stabilization of the wafer to processing temperature prior to processing; (b) selective design of hole patterns on the show-ped to selectively deposition film in different areas of the back-side of the wafer; (c) a carrier ring or optionally multiple swappable rings that can be attached to achieve appropriate plasma confinement, hole pattern, and edge impedance, which may help achieve a desired radial-distribution of film properties; (d) stable wafer transfer mechanisms within chamber and for transferring wafer outside to another chamber or cassette—such as lift pins, RF-coupling features, minimum-contact arrays; (e) implement gas mixing features, e.g., such as inner plenum, baffle and manifold lines openings; (f) add compartments in the gas-flowing pedestal (i.e., show-ped) to enable selective gas flow to different regions of the back side of the wafer and control flow rates via flow controllers and/or multiple plenums, or any combination of these features.

In another embodiment, dynamic gap control using wafer lift mechanism enables: (a) control of the distance from deposition or reactant flowing electrode to the side of the wafer that needs deposition or in the middle so that both sides can be deposited; and (b) the lift mechanism to control the distance dynamically during the deposition process to control the side of the deposition, profile of the deposition, and deposition film properties. In another embodiment, for a deposition mode used to deposit on the back-side of the wafer, film edge exclusion control is highly desirable to avoid lithography-related overlay problems. The lift mechanism used in this system is done via a carrier ring 124 that has a design feature to shadow the deposition on the edge. This specifies the edge exclusion control via the design and shape of the carrier ring.

FIGS. 4A and 4B respectively show bottom and top perspective views of wafer carrier ring 424 formed from multiple materials. As shown in FIGS. 4A and 4B, carrier ring 424 may be formed from an inner ring 426 and an outer ring 428. The inner ring 426 may be formed of a first material having a first impedance, while the outer ring 428 may be formed of a second material have a second impedance different from the first impedance. As one particular example, the inner ring 426 may be formed from one or more metals that provide a relatively low impedance to plasma, while the outer ring 428 may be formed one or more ceramics that provide a relatively high impedance to plasma.

The materials of the inner ring 426 and/or the materials of the outer ring 428 may be selected to provide a tuned plasma impedance that results in deposition of a film having desired properties such as stress levels, uniformity of thickness, etc. For example, when a relatively low impedance along a periphery of a substrate is needed to deposit a film having desired properties such as an increased thickness along the periphery, a fabricator may select an inner ring 426 formed from one or more first metals having relatively low impedance levels such as aluminum. In contrast, when a relatively high impedance along a periphery of a substrate is needed to deposit a film having desired properties such as a reduced thickness along the periphery, a fabricator may select an inner ring 426 formed from a dielectric material such as ceramic.

In general, swapping the inner ring 426 for a version formed from a metallic material may reduce the impedance to ground along the periphery of the substrate being processed, thus increasing the plasma density along the periphery of the substrate. In contrast, swapping the inner ring 426 for a version formed from a dielectric material such as ceramic may increase the impedance to ground along the periphery of the substrate being processed, thus decreasing the plasma density along the periphery of the substrate. In some embodiments, the increase in plasma density may cause a reduction in film thickness along the periphery of the substrate. In other embodiments, depending on the process conditions and processing recipe parameters, the increase in plasma density may cause an increase in film thickness along the periphery of the substrate. Thus, a fabricator can adjust film thickness along the periphery of the substrate by swapping the inner ring 426 for a version formed from a metallic material or formed from a dielectric material in order to obtain an appropriate impedance, which results in an appropriate plasma density, and which then leads to the desired film thickness along the periphery of the substrate depending on the processing conditions and processing recipe parameters.

In some embodiments, the inner ring 426 may be configured to mate with the outer ring 428 in a removable manner. As an example, the outer ring 428 may have an engagement feature such as a groove, shelf, ledge, or recess and the inner ring 426 may be configured to engage with the one or more engagement features of the outer ring 428, such as by resting on or within the one or more engagement features of the outer ring 428. In another example, the inner ring 426 may include the one or more engagement features such as a groove, shelf, ledge, or recess and the outer ring 428 may be configured to engage with the one or more engagement features of the inner ring 426. If desired, the outer ring 428 may include one or more first mating structures, the inner ring 426 may include one or more second mating structures, and the first and second mating structures may engage with each other to hold the inner and outer rings 426 and 428 in rotational alignment with each other. As an example, the inner ring 426 may include one or more mating structures in the form of protrusions 430 that engage with one or more corresponding mating structures in the form of recesses 432 in the outer ring 428. The one or more mating structures of the outer ring 428 and the one or more mating structures of the inner ring 426 may be configured to prevent rotation of the outer ring 428 relative to the inner ring 426 in a first direction about an axis an in a second direction about the axis. Because the inner ring 426 can be separated from the outer ring 428, different versions of the inner ring 426 that are formed from different materials can be easily swapped out, to provide rapid tuning of the wafer carrier ring 424.

The wafer carrier ring 424 formed from multiple materials disclosed herein may be utilized for backside depositions and/or frontside depositions. In both backside and frontside depositions, the wafer carrier ring 424 may provide impedance tuning capabilities, particularly along the periphery of a substrate being processed.

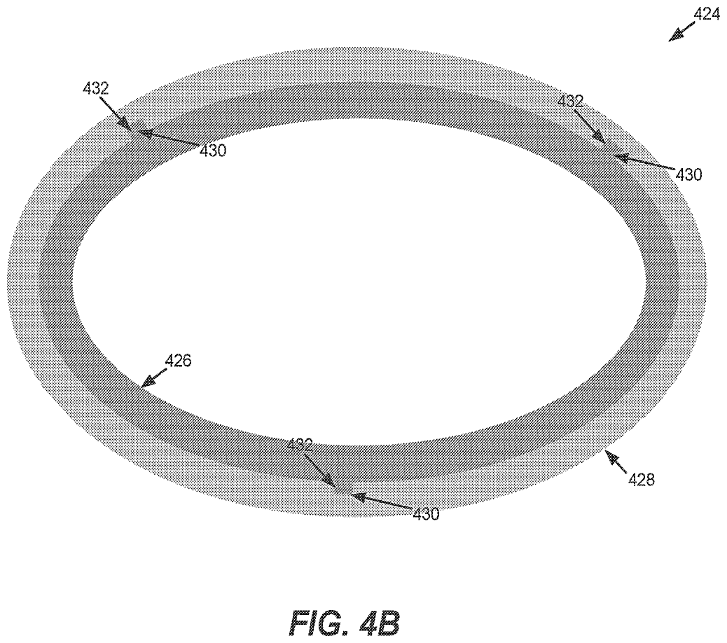

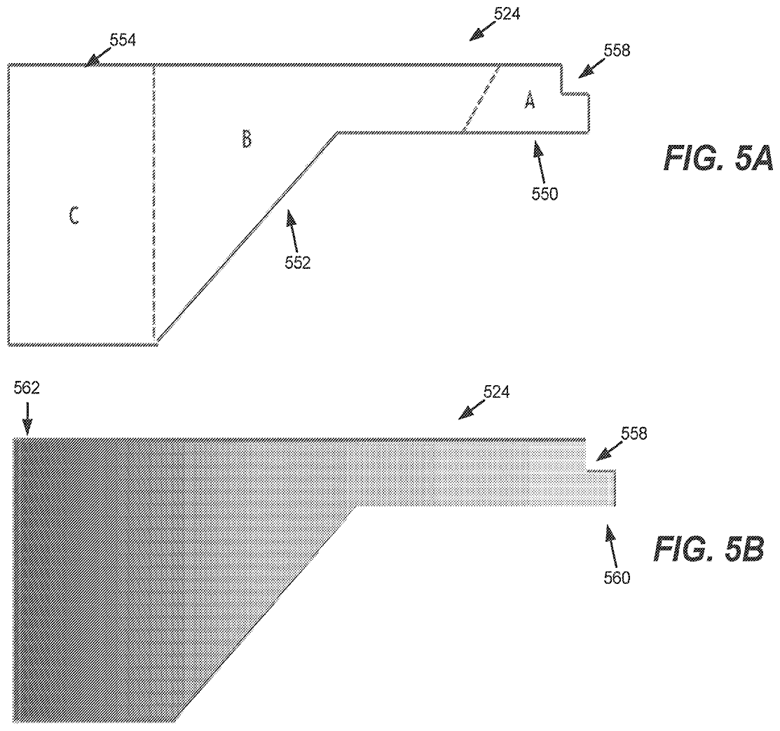

FIG. 5A shows a cross-sectional view of a wafer carrier ring 524 having a radially-varied electrical impedance and FIG. 5B illustrates an example of radially-varying electrical impedance within the wafer carrier ring 524. As shown in FIG. 5B, the electrical impedance within the wafer carrier ring 524 may vary relatively smoothly as a function of radial position within the ring 524 (e.g., there may be a relatively smooth transition between the impedance of the inner region 550 and the impedance of the outer region 554).

Wafer carrier ring 524 may have different electrical impedances as a function of radial position within the ring 524. As an example, an inner region 550 may have a first electrical impedance to plasma, a middle region 552 may have a second electrical impedance, and an outer region 554 may have a third electrical impedance. The magnitude of the second electrical impedance may, in some examples, be between the magnitudes of the first and third electrical impedances. In other configurations, the magnitude of the second electrical impedance is less than, or greater than, the magnitudes of both the first and third electrical impedances. In some configurations, the inner region 550 has a lower electrical impedance to plasma than the middle region 552 and the middle region 552 has a lower electrical impedance to plasma than the outer region 554, such that the edge of a wafer carried by ring 524 is exposed to a higher intensity of plasma. In some embodiments, wafer carrier ring 524 has an impedance that varies relatively smoothly between an inner circumference near inner edge 560 and an outer circumference near outer edge 562.

In some embodiments, wafer carrier ring 524 is formed from a single piece whose electrical impedance varies as a function of radial position. As a first example, the shape of wafer carrier ring 524 may result in radially-varying impedances, as shown in FIGS. 5A and 5B. In particular, the relatively thin inner portion 550 may have a lower or higher electrical impedance as a result of being relatively thin. Additionally, the outer portion 554 may be relatively thick and may have a higher or lower electrical impedance as a result of the additional thickness. Whether the impedance of wafer carrier ring 524 increase or decreases with increasing thickness depends on what material(s) the wafer carrier ring 524 is formed from. As examples, metals will generally have lower impedances in thicker regions of the ring 524 and higher impedances at thinner regions of the ring 524, while ceramics and other insulators will generally have lower impedances in thinner regions of the ring 524 and higher impedances at thicker regions of the ring 524.

As another example of how wafer carrier ring 524 can be formed with electrical impedances that vary as a function of radial position, the wafer carrier ring 524 may be formed of one or more materials that vary radially within the ring 524. As an example, the wafer carrier ring 524 may be formed from a medium such as ceramic impregnated with metal and the density of the metal may vary radially. In such an example, an inner region 550 may have a relatively high density of metal and thus may have a relatively low impedance, while an outer region 554 has a relatively low density of metal and thus a relatively high impedance. Middle region 552 may have an intermediate density of metal and an intermediate impedance between the densities and impedances of the inner and outer regions 550 and 554. In such an example, the carrier ring 524 may be coated with a relatively thin protective cover which could be metal or another suitably plasma-resistant material to prevent plasma from etching away at the carrier ring 524. Such a protective cover may be desired when carrier ring 524 is formed from a material that is otherwise insufficiently plasma-resistant.

As another example of how wafer carrier ring 524 can be formed with electrical impedances that vary as a function of radial position, the wafer carrier ring 524 may be formed of multiple materials that are joined together permanently, semi-permanently, or removably. As an example, inner region 550 (e.g., region A) may be formed of a first metal having a relatively low impedance to plasma, middle region 552 (e.g., region B) may be formed of a second metal having an intermediate impedance to plasma, and outer region 554 (e.g., region C) may be formed of a third metal having a relatively high impedance to plasma, where all three metals are permanently joined by any desired technique such as using soldering, welding, gluing, permanent or semi-permanent fasteners, and/or any combination of these and other joining techniques whether chemical, mechanical, magnetic, or otherwise.

As shown in FIGS. 5A and 5B, wafer carrier ring 524 may include a notch 558 or other structure. The notch 558 may be configured to hold a wafer during processing and/or transport. Notch 558 may also be referred to as a ledge and may extend around an inner circumference of the wafer carrier ring 524.

The wafer carrier ring 524 having radially-varied plasma impedances may be utilized for backside depositions and/or frontside depositions. In both backside and frontside depositions, the wafer carrier ring 524 may provide impedance tuning capabilities, particularly along the periphery of a substrate being processed.

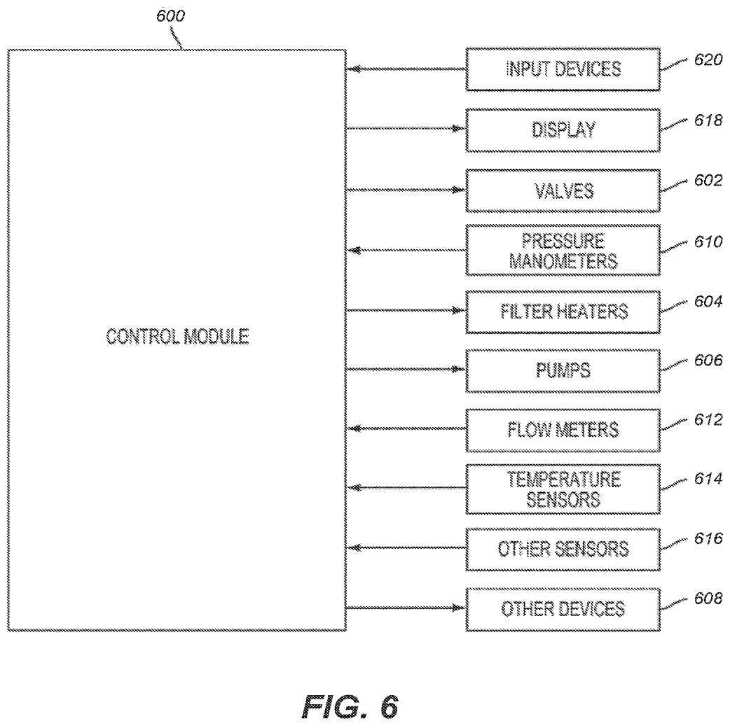

FIG. 6 shows a control module 600 for controlling the systems described above. In one embodiment, the control module 110 of FIG. 1 may include some of the example components. For instance, the control module 600 may include a processor, memory and one or more interfaces. The control module 600 may be employed to control devices in the system based in part on sensed values. For example only, the control module 600 may control one or more of valves 602, filter heaters 604, pumps 606, and other devices 608 based on the sensed values and other control parameters. The control module 600 receives the sensed values from, for example only, pressure manometers 610, flow meters 612, temperature sensors 614, and/or other sensors 616. The control module 600 may also be employed to control process conditions during precursor delivery and deposition of the film. The control module 600 will typically include one or more memory devices and one or more processors.

The control module 600 may control activities of the precursor delivery system and deposition apparatus. The control module 600 executes computer programs including sets of instructions for controlling process timing, delivery system temperature, pressure differentials across the filters, valve positions, mixture of gases, chamber pressure, chamber temperature, wafer temperature, RF power levels, wafer chuck or pedestal position, and other parameters of a particular process. The control module 600 may also monitor the pressure differential and automatically switch vapor precursor delivery from one or more paths to one or more other paths. Other computer programs stored on memory devices associated with the control module 600 may be employed in some embodiments.

Typically there will be a user interface associated with the control module 600. The user interface may include a display 618 (e.g., a display screen and/or graphical software displays of the apparatus and/or process conditions), and user input devices 620 such as pointing devices, keyboards, touch screens, microphones, etc.

Computer programs for controlling delivery of precursor, deposition and other processes in a process sequence can be written in any conventional computer readable programming language: for example, assembly language, C, C++, Pascal, Fortran or others. Compiled object code or script is executed by the processor to perform the tasks identified in the program.

The control module parameters relate to process conditions such as, for example, filter pressure differentials, process gas composition and flow rates, temperature, pressure, plasma conditions such as RF power levels and the low frequency RF frequency, cooling gas pressure, and chamber wall temperature.

The system software may be designed or configured in many different ways. For example, various chamber component subroutines or control objects may be written to control operation of the chamber components necessary to carry out the inventive deposition processes. Examples of programs or sections of programs for this purpose include substrate positioning code, process gas control code, pressure control code, heater control code, and plasma control code.

A substrate positioning program may include program code for controlling chamber components that are used to load the substrate onto a pedestal or chuck and to control the spacing between the substrate and other parts of the chamber such as a gas inlet and/or target. A process gas control program may include code for controlling gas composition and flow rates and optionally for flowing gas into the chamber prior to deposition in order to stabilize the pressure in the chamber. A filter monitoring program includes code comparing the measured differential(s) to predetermined value(s) and/or code for switching paths. A pressure control program may include code for controlling the pressure in the chamber by regulating, e.g., a throttle valve in the exhaust system of the chamber. A heater control program may include code for controlling the current to heating units for heating components in the precursor delivery system, the substrate and/or other portions of the system. Alternatively, the heater control program may control delivery of a heat transfer gas such as helium to the wafer chuck.

Examples of sensors that may be monitored during deposition include, but are not limited to, mass flow control modules, pressure sensors such as the pressure manometers 610, and thermocouples located in delivery system, the pedestal or chuck (e.g. the temperature sensors 614). Appropriately programmed feedback and control algorithms may be used with data from these sensors to maintain desired process conditions. The foregoing describes implementation of embodiments of the invention in a single or multi-chamber semiconductor processing tool.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

Any suitable chamber may be used to implement the disclosed embodiments. Example deposition apparatuses include, but are not limited to, apparatus from the ALTUS® product family, the VECTOR® product family, and/or the SPEED® product family, each available from Lam Research Corp., of Fremont, Calif., or any of a variety of other commercially available processing systems. Two or more of the stations may perform the same functions. Similarly, two or more stations may perform different functions. Each station can be designed/configured to perform a particular function/method as desired.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general purpose processor. System control software may be coded in any suitable computer readable programming language.

The computer program code for controlling processes in a process sequence can be written in any conventional computer readable programming language: for example, assembly language, C, C++, Pascal. Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe, and may be entered utilizing the user interface. Signals for monitoring the process may be provided by analog and/or digital input connections of the system controller. The signals for controlling the process are output on the analog and digital output connections of the deposition apparatus.

The system software may be designed or configured in many different ways. For example, various chamber component subroutines or control objects may be written to control operation of the chamber components necessary to carry out the deposition processes (and other processes, in some cases) in accordance with the disclosed embodiments. Examples of programs or sections of programs for this purpose include substrate positioning code, process gas control code, pressure control code, and heater control code.

In some implementations, a controller is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In sonic examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

In this application, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication thereon. A wafer or substrate used in the semiconductor device industry typically has a diameter of 200 or 300 mm, though the industry is moving toward adoption of 450 mm diameter substrates. The description herein uses the terms “front” and “back” to describe the different sides of a wafer substrate. It is understood that the front side is where most deposition and processing occurs, and where the semiconductor devices themselves are fabricated. The back side is the opposite side of the wafer, which typically experiences minimal or no processing during fabrication.

The flow rates and power levels provided herein are appropriate for processing on 300 mm substrate, unless otherwise specified. One of ordinary skill in the art would appreciate that these flows and power levels may be adjusted as necessary for substrates of other sizes. The following detailed description assumes the invention is implemented on a wafer. However, the invention is not so limited. The work piece may be of various shapes, sizes, and materials. In addition to semiconductor wafers, other work pieces that may take advantage of this invention include various articles such as printed circuit boards and the like.

The apparatus/process described herein may be used in conjunction with lithographic patterning tools or processes, for example, for the fabrication or manufacture of semiconductor devices, displays, LEDs, photovoltaic panels and the like, Typically, though not necessarily, such tools/processes will be used or conducted together in a common fabrication facility. Lithographic patterning of a film typically includes some or all of the following operations, each operation enabled with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted. etching tool; and (6) removing the resist using a tool such as an RF or microwave plasma resist stripper.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A carrier ring, the carrier ring comprising:
an outer ring formed a dielectric material and having an engagement feature; and
an inner ring formed from a metal, wherein the inner ring engages with the engagement feature of the outer ring and wherein the inner ring is configured to support a semiconductor wafer during processing within a processing chamber.

2. The carrier ring of claim 1, wherein the dielectric material comprises ceramic.

3. The carrier ring of claim 1, wherein the metal comprises aluminum.

4. The carrier ring of claim 1, wherein the outer ring comprises first mating structures, wherein the inner ring comprises second mating structures, and wherein the first and second mating structures engage with each other to hold the inner ring and the outer ring in rotational alignment.

5. The carrier ring of claim 4, wherein the first mating structures of the outer ring and the second mating structures of the inner ring are collectively configured to prevent rotation of the outer ring relative to the inner ring in a first direction about an axis and in a second direction about the axis.

6. The carrier ring of claim 5, wherein the first mating structures comprise at least one recess in the outer ring and wherein the second mating structures comprise at least one protrusion on the inner ring.

7. The carrier ring of claim 1, wherein the engagement feature comprises a ledge and wherein the inner ring is configured to rest on the ledge.

8. A plasma processing system, comprising,
a shower-pedestal; and
a substrate support, wherein the substrate support comprises:
an inner portion with a first plasma impedance, the inner portion being configured to hold a substrate at a spaced apart relationship from the shower-pedestal; and
an outer portion with a second plasma impedance, the second plasma impedance being different than the first plasma impedance.

9. The plasma processing system of claim 8, wherein the substrate support further comprises an additional inner portion with a third plasma impedance, wherein the third plasma impedance is different than both the first plasma impedance and the second plasma impedance, and wherein the substrate support is configured such that the inner portion can be swapped out for the additional inner portion such that the additional inner portion, rather than the inner portion, is configured to hold the substrate at the spaced apart relationship from the shower-pedestal.

10. The plasma processing system of claim 8, wherein the inner portion comprises an inner ring, wherein the outer portion comprises an outer ring, and wherein the inner ring and the outer ring each comprise one or more mating structures configured to hold the inner ring in rotational alignment with the outer ring.

11. The plasma processing system of claim 10, wherein the one or mating structures of the outer ring and the one or more mating structures of the inner ring are collectively configured to prevent rotation of the outer ring relative to the inner ring in a first direction about an axis and in a second direction about the axis.

12. The plasma processing system of claim 8, wherein the inner portion comprises metal.

13. The plasma processing system of claim 12, wherein the outer portion comprises dielectric.

14. The plasma processing system of claim 12, wherein the outer portion comprises a ceramic.

15. The plasma processing system of claim 8, wherein the substrate support comprises a carrier ring, the plasma processing system further comprising:
a first processing chamber including the shower-pedestal;
a second processing chamber; and
an indexer configured to move the carrier ring from the first processing chamber to the second processing chamber, wherein the carrier ring is configured to hold the substrate while the indexer moves the carrier ring from the first processing chamber to the second processing chamber.

16. The plasma processing system of claim 8, further comprising:
a gas manifold coupled to the shower-pedestal and configured to provide a gas from a gas source; and
a radio-frequency (RF) power supply configured to provide power to the shower-pedestal to generate a plasma from the gas as part of depositing a film on a backside of the substrate while the substrate is supported by the inner portion in the spaced apart relationship from the shower-pedestal.

17. The plasma processing system of claim 8, wherein the inner portion and the outer portion are formed of a common material, wherein the inner portion has a first thickness, wherein the outer portion has a second thickness, and wherein the first thickness is less than the second thickness such that the second plasma impedance is different than the first plasma impedance.

18. The plasma processing system of claim 8, wherein the inner portion and the outer portion are formed of a first material and a radially-varying concentration of a second material, wherein the inner portion has a first concentration of the second material, wherein the outer portion has a second concentration of the second material, and wherein the first concentration is different than the second concentration such that the second plasma impedance is different than the first plasma impedance.

19. The plasma processing system of claim 8, wherein the inner portion and the outer portion are formed of a first material and a radially-varying concentration of a conductor within the first material, wherein the inner portion has a first concentration of the conductor, wherein the outer portion has a second concentration of the conductor, and wherein the first concentration is greater than the second concentration such that the first plasma impedance, associated with the inner portion, is greater than the second plasma impedance, associated with the outer portion.

20. The plasma processing system of claim 8, wherein the inner portion comprises an inner circumference having a ledge, the ledge being configured to hold the substrate at the spaced apart relationship from the shower-pedestal.
